(19) United States
(12) Patent Application Publication
(10) Pub. No.: US 2025/0359187 A1
(43) Pub. Date: Nov. 20, 2025

(54) SEMICONDUCTOR STRUCTURE HAVING VERTICAL CHANNELS AND METHOD FOR MANUFACTURING THE SAME

(71) Applicant: TAIWAN SEMICONDUCTOR MANUFACTURING COMPANY, LTD., Hsinchu (TW)

(72) Inventors: Ken-Ichi GOTO, Hsinchu (TW); Gerben DOORNBOS, Hsinchu (TW)

(73) Assignee: TAIWAN SEMICONDUCTOR MANUFACTURING COMPANY, LTD., Hsinchu (TW)

(21) Appl. No.: 18/666,982

(22) Filed: May 17, 2024

(51) Int. Cl. H01L 29/786; H01L 29/423; H01L 29/66

(52) U.S. Cl. CPC H10D 30/6757; H10D 30/0321; H10D 30/6735; H10D 30/6755

(57) ABSTRACT

A method for manufacturing a semiconductor structure includes: depositing atomic layers of tin monoxide along a vertical direction; patterning the atomic layers of tin monoxide into a channel unit; forming a first conducting oxide unit that is connected to the channel unit; forming a second conducting oxide unit that is connected to the channel unit and that is spaced apart from the first conducting oxide unit so as to permit charge carriers to be transmitted between the first conducting oxide unit and the second conducting oxide unit through the patterned atomic layers in the channel unit along the vertical direction; forming a gate dielectric over the channel unit, the first and second conducting oxide units; forming a metal gate over the gate dielectric; recessing the metal gate to expose the gate dielectric; and partially removing the gate dielectric to expose at least the first conducting oxide unit.

### BACKGROUND

Thin film transistors are widely used in back-end-of-line process, and semiconductor oxide serve as a compatible material for forming channels of the thin film transistors. Novel structures and manufacturing processes of thin film transistors are being continuously developed to maximize advantages of the unique properties of semiconductor oxide, so as to enhance performance of the thin film transistors made from semiconductor oxide.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a first method for manufacturing a first semiconductor structure in accordance with some embodiments.

FIGS. 2 to 10 are schematic views illustrating intermediate stages of the first method for manufacturing the first semiconductor structure in accordance with some embodiments.

FIG. 11 is a flow diagram illustrating a second method for manufacturing a second semiconductor structure in accordance with some embodiments.

FIGS. 12 to 21 are schematic views illustrating intermediate stages of the second method for manufacturing the second semiconductor structure in accordance with some embodiments.

FIG. 22 is a flow diagram illustrating a third method for manufacturing a third semiconductor structure in accordance with some embodiments.

FIGS. 23 to 32 are schematic views illustrating intermediate stages of the third method for manufacturing the third semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects±10%, in some aspects ±5%, in some aspects±2.5%, in some aspects±1%, in some aspects±0.5%, and in some aspects±0.1% from the specified amount, as such variations are appropriate to perform the disclosed methods or employ the disclosed compositions.

The present disclosure is directed to a semiconductor structure having vertical channels that are made of a semiconductor oxide, and a method for manufacturing the same. In some embodiments, the semiconductor structure is a thin film transistor. In order to prepare a p-type thin film transistor, the semiconductor oxide may be tin monoxide (SnO, known as tin (II) oxide), which has a multi-layered atomic structure, i.e., the tin monoxide molecules are arranged into atomic layers that are stacked along a vertical direction (or known as direction, or out-of-plane direction), and in each of the atomic layers, the tin monoxide molecules are arranged to extend along a horizontal direction (or known as direction, or in-plane direction) transverse to the vertical direction. It is noted that hole mobility of tin monoxide in the vertical direction is much greater (e.g., 10 times greater) than that of tin monoxide in the horizontal direction (with reference to Hu, Y. et al. (2022), ACS Applied Materials & Interfaces, 14, 25670-25679; doi: 10.1021/acsami.2c03554). Thus, in the present disclosure, in order to take the advantage of tin monoxide having high mobility in the vertical direction, the vertical tin monoxide channels are prepared to permit charge carriers to be transmitted therethrough in the vertical direction. In addition, the vertical channels are spaced apart from each other in the horizontal direction, and are each surrounded by a metal gate. Such configuration enables a relatively large total channel width (measured along surfaces of the vertical channels covered by the metal gate) per unit area of such configuration occupied on a base structure, thereby allowing a large total current to flow through the vertical channels. Furthermore, a gate length of the thin film transistor is equivalent to a height of each of the vertical channels (measured along the vertical direction), and can be well controlled.

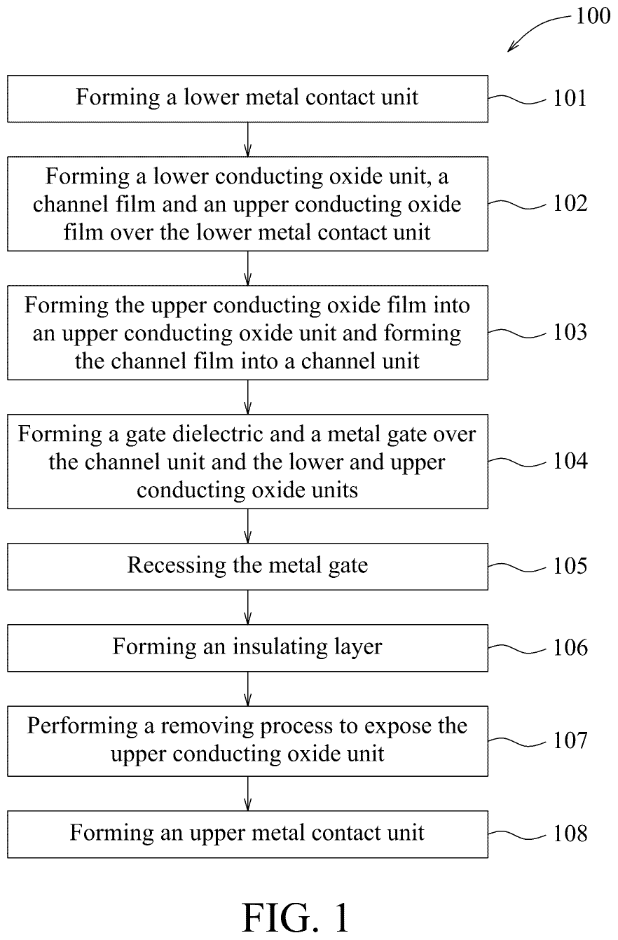

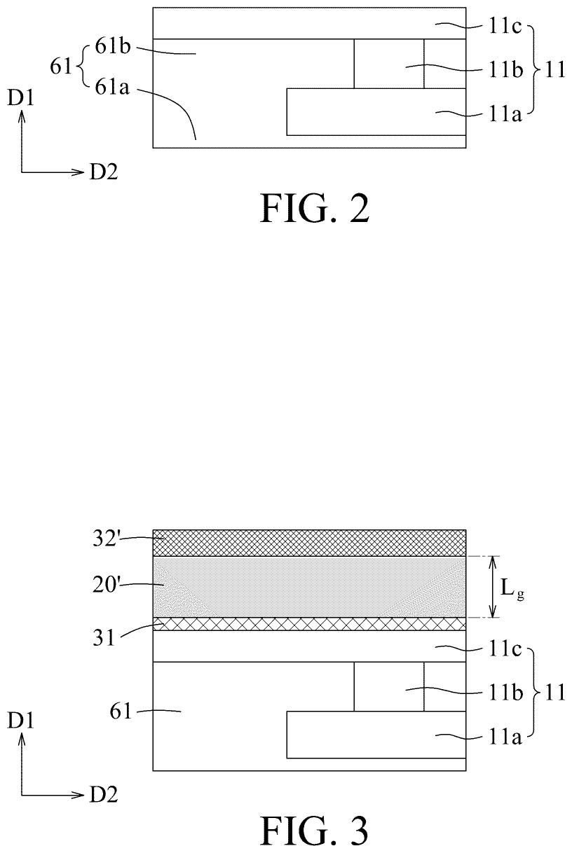

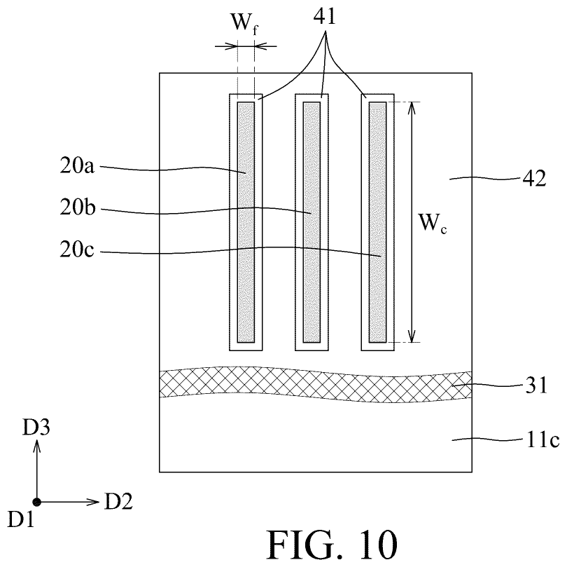

FIG. 1 is a flow diagram illustrating a first method 100 for manufacturing a first semiconductor structure (for example, the semiconductor structure 1000 shown in FIG. 9) in accordance with some embodiments. FIGS. 2 to 9 illustrate schematic views of intermediate stages of the method 100 in accordance with some embodiments. Some repeating structures are omitted in FIGS. 2 to 9 for the sake of brevity. Additional steps can be provided before, after or during the method, and some of the steps described herein may be replaced by other steps or be eliminated. FIG. 10 is a horizontal cross sectional view taken along line A-A shown in FIG. 9.

Referring to FIG. 1 and the example illustrated in FIG. 2, the method 100 begins at step 101, where a metal contact unit 11 is formed in a base structure.

The base structure may include any suitable devices, or interconnecting elements, that are obtained from e.g., the front-end-of-line process, the middle-end-of-line process, or the back-end-of-line process. In FIG. 2, only a dielectric portion 61 and the metal contact unit 11 of the base structure is shown. The dielectric portion 61 may include silicon oxide, silicon nitride, or other suitable materials, or combinations thereof, but is not limited thereto.

The metal contact unit 11 serve as a source contact unit for a thin film transistor, i.e., the semiconductor structure 1000 shown in FIG. 9, such that charge carriers enter the channel unit 20 (see FIG. 9) through the metal contact unit 11. In some embodiments, the metal contact unit 11 includes a source contact 11a formed in a lower dielectric 61a of the dielectric portion 61, a via 11b formed in an upper dielectric 61b of the dielectric portion 61, and a metal contact 11c formed over the dielectric portion 61. The source contact 11a, the via 11b, and the metal contact 11c are connected to each other. Each of the source contact 11a, the via 11b, and the metal contact 11c may independently include gold (Au), platinum (Pt), nickel (Ni), indium tin oxide (ITO), tungsten (W), titanium nitride (TiN), Iridium (Ir), Palladium (Pd), Cobalt (Co), Rhodium (Rh), Ruthenium (Ru), Osmium (Os) or other suitable materials, or combinations thereof, but are not limited thereto. Other suitable materials and/or configurations for the metal contact unit 11 are within the contemplated scope of the present disclosure. The metal contact unit 11 may be formed using any suitable methods known in the art. In some embodiments, the metal contact 11c may have a thickness greater than approximately 5 nm.

Referring to FIG. 1 and the example illustrated in FIG. 3, the method 100 proceeds to step 102, where a lower conducting oxide film 31, a channel film 20′ and an upper conducting oxide film 32′ are sequentially formed over the metal contact unit 11 and the base structure.

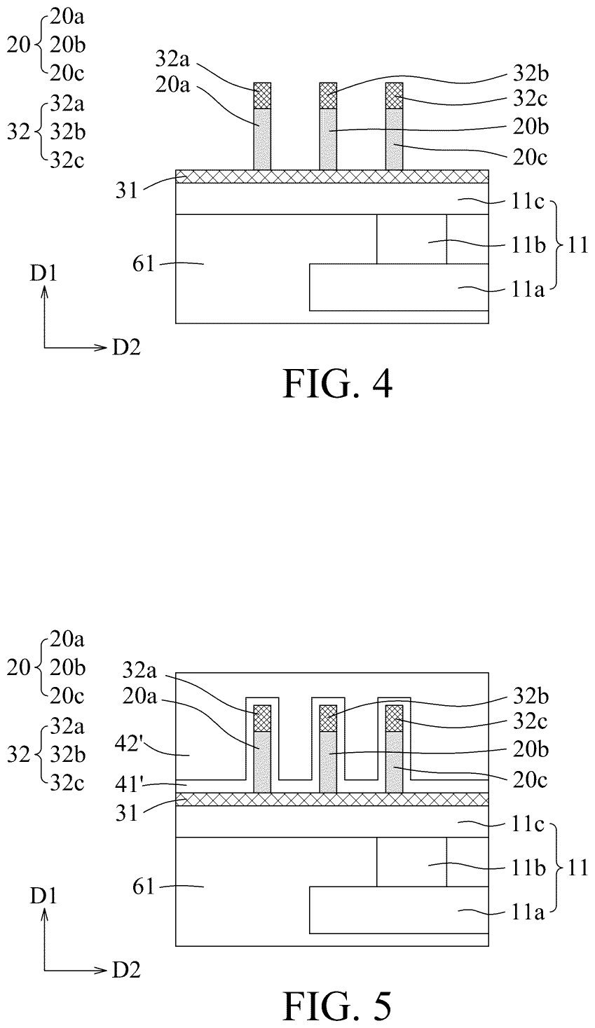

Each of the lower conducting oxide film 31 and the upper conducting oxide film 32′ may independently include a conducting oxide, or more specifically, an oxide-based material that is electrically conductive. In some embodiments, the conducting oxide may include indium tin oxide (InSnO, or known as ITO), indium oxide (InO), or other suitable materials, or combinations thereof, but are not limited thereto. As shown in FIG. 3, the lower conducting oxide film 31 and the upper conducting oxide film 32′ are located on opposite sides of the channel film 20′ in a vertical direction D1. Each of the lower conducting oxide film 31 and the upper conducting oxide film 32′ may have a thickness not greater than 500 nm, in view of a maximum height of a via element in back-end-of-line (BEOL) of the semiconductor structure. In some embodiments, the lower conducting oxide film 31 may have a thickness ranging from about 3 nm to about 100 nm. If the lower conducting oxide film 31 is too thin (e.g., less than about 3 nm), a sheet resistance thereof may be undesirably large. In certain embodiments, the upper conducting oxide film 32′ may have a thickness ranging from about 3 nm to about 50 nm. If the upper conducting oxide film 32′ is too thin (e.g., less than about 3 nm), a uniformity of conducting features 32a, 32b, 32c (see FIG. 4) obtained therefrom after performing the subsequent step 103 may be undesired.

In some embodiments, the channel film 20′ may include a semiconductor oxide, such as tin monoxide (SnO, or known as tin (II) oxide), nickel oxide (NiO), indium gallium zinc oxide (IGZO), indium oxide (InOₓ), indium tin oxide (ITO), copper monoxide (Cu₂O), indium tungsten oxide (IWO) or other suitable materials, or combinations thereof, but are not limited thereto. In some embodiments, in order to form an n-type thin film transistor, the channel film 20′ may include indium gallium zinc oxide (IGZO), indium oxide (InOₓ), indium tin oxide (ITO), indium tungsten oxide (IWO), or other suitable materials, or combinations thereof, but are not limited thereto. In other embodiments, in order to form a p-type thin film transistor, the channel film 20′ may include nickel oxide (NiO), copper monoxide (Cu₂O), tin monoxide (SnO), or other suitable materials, or combinations thereof, but are not limited thereto. For instance, in certain embodiments, in order to form a p-type thin film transistor with high mobility, the channel film 20′ is made of tin monoxide by, e.g., atomic layered deposition (ALD) or physical vaper deposition (PVD). In the channel film 20′, atomic layers of tin monoxide are deposited and stacked on each other over the lower conducting oxide film 31 along the vertical direction D1 (or known as direction, or out-of-plane direction). Each of the atomic layers of tin monoxide extends along a horizontal direction D2 (or known as direction, or in-plane direction) which is transverse, e.g., perpendicular to, the vertical direction D1. It is noted that tin monoxide has a hole mobility in the vertical direction D1 approximately 10 times higher than that in the horizontal direction D2. In some embodiments, charge carriers are transmitted in the vertical direction D1 by a first speed, and are transmitted in the horizontal direction D2 by a second speed, and the first speed is faster than the second speed by e.g., approximately 10 times. In the present disclosure, in order to take advantage of tin monoxide having such a high hole mobility in vertical direction D1, the channel film 20′ made of tin monoxide is to be formed into vertical channels 20a, 20b, 20c (see FIG. 4, will be described in step 103 hereinafter). Such vertical channels 20a, 20b, 20c, in cooperation with other elements of the thin film transistor, are capable of accomplishing transmission of charge carriers therethrough in the vertical direction D1. In some embodiments, the tin monoxide has a single crystal structure, so as to achieve high hole mobility (e.g., approximately greater than 10 cm²/Vs). In other embodiments, the tin monoxide has a polycrystalline structure. In certain embodiments, the channel film 20′ may have a height (L_{g}) ranging from about 5 nm to about 100 nm. If the height (L_{g}) is too small, the vertical channels 20a, 20b, 20c produced from the channel film 20′ might be induced with a short channel effect, resulting in a poor control of an off-current (I_{off}) in operation of the thin film transistor. If the height (L_{g}) is too large, degradation of drain current might occur, and gate capacitance could be increased, which undesirably degrades switching speed of the thin film transistor. Other suitable materials and/or methods for forming the lower conducting oxide film 31, the channel film 20′ and the upper conducting oxide film 32′ are within the contemplated scope of the present disclosure.

Referring to FIG. 1 and the example illustrated in FIG. 4, the method 100 proceeds to step 103, where a patterning process is performed to form the upper conducting oxide film 32′ (see FIG. 3) into a conducting oxide unit 32, and to from the atomic layers of tin monoxide in the channel film 20′ (see FIG. 3) into a channel unit 20.

The channel unit 20 includes at least one vertical channel, which extends in the vertical direction D1 to terminate at an upper end and a lower end. Please note that number of the vertical channel(s) may be determined according to practical needs. For instance, as shown in FIG. 4, three vertical channels, respectively denoted by the numerals 20a, 20b, and 20c, are formed, but are not limited thereto. The three vertical channels 20a, 20b, 20c serve as channels for the thin film transistor of the semiconductor structure 1000 shown in FIG. 9. The vertical channels 20a, 20b, 20c are spaced apart from each other along the horizontal direction D2.

Each of the vertical channels 20a, 20b, 20c may have the height (L_{g}) (measured along the vertical direction D1, see FIG. 9) which is also known as a gate length of the thin film transistor, and which is equivalent to the thickness of the channel film 20′ as discussed in FIG. 3. That is, the gate length of the thin film transistor could be easily and well controlled by simply adjusting thickness of the charnel film 20′ (see FIG. 2) formed in step 102. Each of the vertical channels 20a, 20b, 20c may have a thickness (W_{f}) (measured along the horizontal direction D2, see FIG. 10) ranging from about 3 nm to about 20 nm. If the thickness (W_{f}) is too small, gate leakage current might be undesirably large. If the thickness (W_{f}) is too large, an area required to form the thin film transistor might undesirably increase. Each of the vertical channels 20a, 20b, 20c may have a channel width (W_{c}) (measured along a direction D3 transverse to both the vertical direction D1 and the horizontal direction D2, see FIG. 10) greater than approximately 3 nm.

The conducting oxide unit 32 is to be connected to the conducting oxide unit 12 (see FIG. 9) which serves as a drain contact unit of the thin film transistor. The conducting oxide unit 32 includes at least one conducting feature. Please note that the number of the conducting feature(s) corresponds to the number of the vertical channel(s). For instance, as shown in FIG. 4, there are three of the conducting features, respectively denoted by the numerals 32a, 32b, 32c formed, and respectively disposed on and in position corresponding to the vertical channels 20a, 20b, 20c.

Please note that any suitable methods known in the art may be applied to perform the patterning process in step 103. In some embodiments, the patterning process first includes patterning the upper conducting oxide film 32′ (see FIG. 3) into the conducting features 32a, 32b, 32c, and then patterning the channel film 20′ (see FIG. 3) into the vertical channels 20a, 20b, 20c through the conducting features 32a, 32b, 32c. The active chemicals for patterning the upper conducting oxide film 32′ and the channel film 20′ may be different, so as to avoid undesired damage to the channel film 20′, or the lower conducting oxide film 31, or the conducting features 32a, 32b, 32c. Other suitable methods for forming the channel unit 20 and the conducting oxide unit 32 are within the contemplated scope of the present disclosure. In some embodiments, the lower conducting oxide film 31 formed in FIG. 3 is not patterned, and directly serves as a conducting oxide unit 31 hereinafter.

By completing step 103, the conducting oxide units 31, 32 are formed to be spaced apart from and are located opposite to each other in the vertical direction D1. Specifically, the conducting features 32a, 32b, 32c of the conducting oxide unit 32 are disposed on and in direct contact with the upper ends of the vertical channels 20a, 20b, 20c, respectively; while the conducting oxide unit 31 is disposed beneath and in direct contact with the lower end of each of the vertical channels 20a, 20b, 20c. As such, charge carriers are transmitted between the first conducting oxide unit 32 and the second conducting oxide unit 31 through the vertical channels 20a, 20b, 20c in the vertical direction D1.

The vertical channels 20a, 20b, 20c, which are spaced apart from each other in the horizontal direction D2, are surrounded by a metal gate 42 that is to be formed subsequently (see FIG. 9) in the thin film transistor. Specifically, each of the vertical channels 20a, 20b, 20c has sidewalls that connect the upper end and the lower end of each of the vertical channels 20a, 20b, 20c and that are each at least partially covered by the metal gate 42. Such configuration enables the channel unit 20 to have a large total channel width without occupying a large area on the base structure. For instance, as shown in FIG. 10, each of the vertical channels 20a, 20b, 20c has two sidewalls opposite to each other in the horizontal direction D2, thereby having a total channel width of 2W_{c}, meaning that the channel unit 20, which has three of the vertical channels 20a, 20b, 20c, has a total channel width of 6W_{c}. In contrast, in a case of a back-gated thin film transistor having a source contact and a drain contact disposed on a top surface of a horizontal channel, and a metal gate disposed on a bottom surface of the horizontal channel, the horizontal channel having the same dimension as that of the channel film 20′ formed in step 102 (see FIG. 2) would have a channel width of at most equal to the length, or the width (e.g., W_{c} as shown in FIG. 10) of the channel film 20′. That is, the thin film transistor prepared in accordance with the present disclosure has a total channel width which is much larger compared to the channel width of the horizontal channel, thereby allowing a large total current to flow through the channel unit 20.

Referring to FIG. 1 and the example illustrated in FIG. 5, the method 100 proceeds to step 104, where a gate dielectric 41′ and a metal gate 42′ is formed over the channel unit 20, and the conducting oxide units 31, 32.

Specifically, the gate dielectric 41′ is first formed over the structure shown in FIG. 4 in a conformal manner, such that the conducting oxide unit 31, the vertical channels 20a, 20b, 20c of the channel unit 20, and the conducting features 32a, 32b, 32c of the conducting oxide unit 32 are entirely covered by the gate dielectric 41′, while portions of the gate dielectric 41′ surrounding the sidewalls of the vertical channels 20a, 20b, 20c are spaced apart from each other to form a clearance (not shown) among each of the vertical channels 20a, 20b, 20c. The gate dielectric 41′ may include a dielectric material with high dielectric constant, such as hafnium oxide (HfO₂), aluminum oxide (Al₂O₃), silicon oxide (SiO₂), or other suitable materials, or combinations thereof, but are not limited thereto. In some embodiments, the gate dielectric has a thickness ranging from about 3 nm to about 30 nm.

The metal gate 42′ is then formed over the gate dielectric 41′, such that the metal gate 42′ is spaced apart from the conducting oxide units 31, 32 and the channel unit 20 by the gate dielectric 41′. In some embodiments, the metal gate 42′ fills the clearance among the portions of the gate dielectric 41′ that are located on sidewalls of the vertical channels 20a, 20b, 20c, such that the metal gate 42′ surrounds each of the vertical channels 20a, 20b, 20c. The metal gate 42′ may include tungsten (W), titanium nitride (TiN), tantalum nitride (TaN), platinum (Pt), nickel (Ni), or other suitable materials, or combinations thereof, but are not limited thereto.

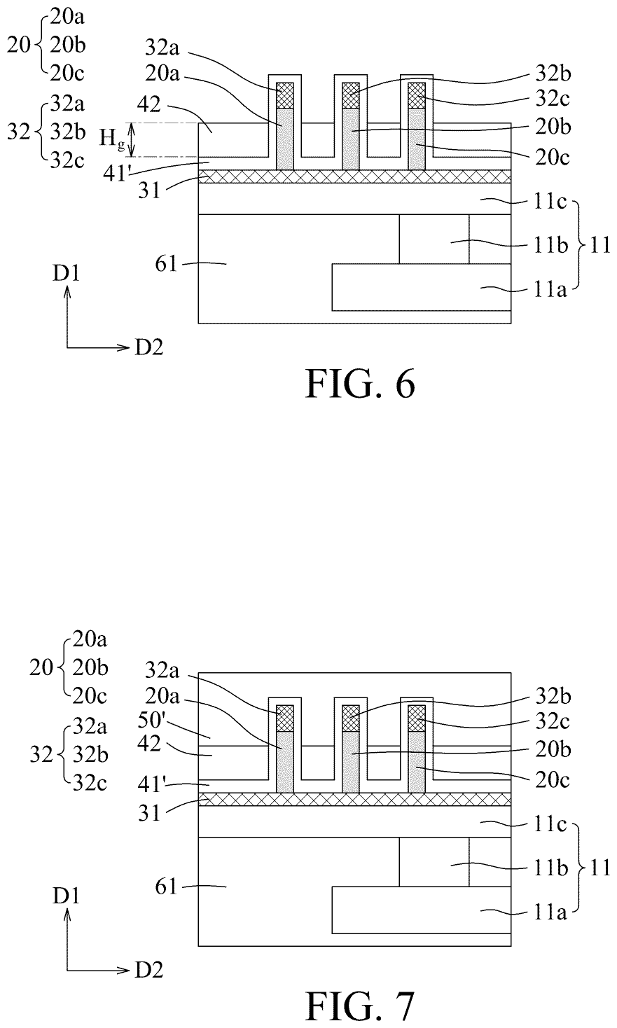

Referring to FIG. 1 and the example illustrated in FIG. 6, the method 100 proceeds to step 105, where the metal gate 42′ (see FIG. 5) is recessed to expose the gate dielectric 41′. The recessed metal gate is denoted by the numeral 42 hereinafter.

The recessing may be performed using any suitable method known in the art, so as to achieve a desired height (Hg) of the recessed metal gate 42. The height (Hg) may be greater than approximately 5 nm, but is not limited thereto. In some embodiment, the height (Hg) that is similar to, or slightly larger than the height (L_{g}) (see FIG. 9) of the vertical channels 20a, 20b, 20c. For instance, a ratio of the height (Hg) to height (L_{g}) may be approximately 0.8 to 1.2. If the ratio is too small, an external resistance, or known as an interface resistance between the metal gate 42 and the metal contact unit 11 (the source contact unit of the thin film transistor) would be too high. If the ratio is too high, gate capacitance would be too high. After the recessing, parts of the gate dielectric 41′ are exposed from and in some embodiments, protruded away from the recessed metal gate 42.

Referring to FIG. 1 and the example illustrated in FIG. 7, the method 100 proceeds to step 106, where an insulating layer 50′ is formed over the structure shown in FIG. 6, so as to cover the metal gate 42.

The insulating layer 50′ may be formed using any suitable method known in the art. In some embodiments, the insulating layer 50′ includes silicon nitride, or other suitable materials, or combinations thereof, but is not limited thereto.

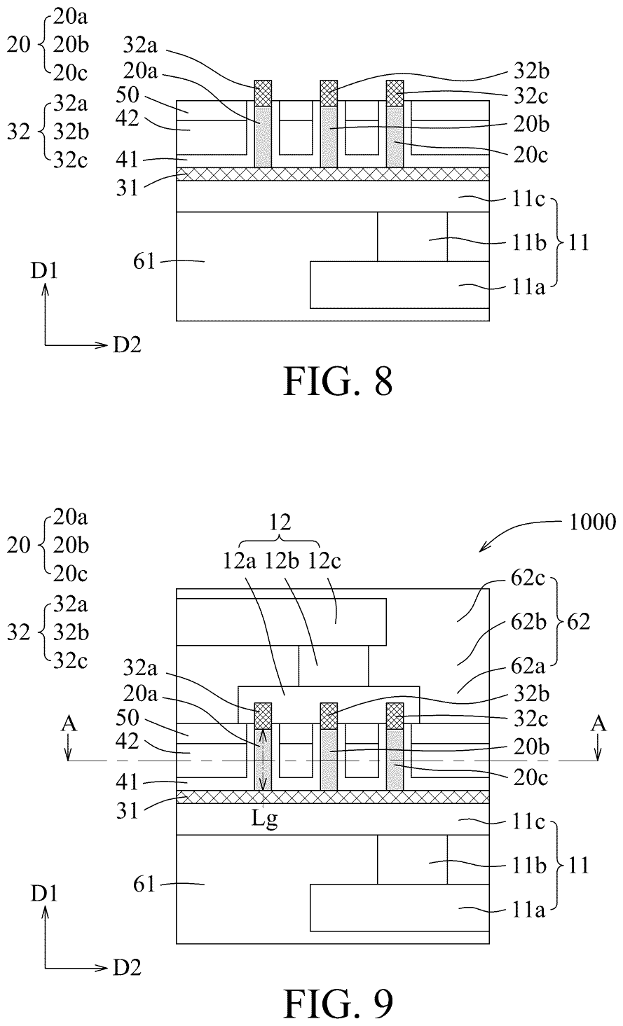

Referring to FIG. 1 and the example illustrated in FIG. 8, the method 100 proceeds to step 107, where a removing process is performed to partially remove the insulating layer 50′ and the gate dielectric 41′ (see FIG. 7), so as to expose the conducting oxide unit 32.

In some embodiments, the removing process may, for instance, first include a chemical mechanical planarization process (CMP), followed by a recessing process, but is not limited thereto. For instance, the CMP process may remove a portion of the insulating layer 50′ so as to expose the gate dielectric 41′. In some embodiments, the CMP process may further remove portions of the gate dielectric 41′ disposed above the conducting oxide unit 32. The recessing process may further remove portions of the insulating layer 50′ and portions of the gate dielectric 41′, so as to form the recessed insulating layer, and the recessed gate dielectric, which are respectively denoted by the numerals 50 and 41. The recessing process terminates until the recessed insulating layer 50 reaches a predetermined height, such as approximately greater than 3 nm, but is not limited thereto. In some embodiments, the predetermined height is greater than approximately 3 nm, but is not limited thereto. The recessing process may be any suitable method known in the art, such as an etching process, but is not limited thereto. As such, the conducting oxide unit 32 is exposed from the recessed insulating layer 50, while the insulating layer 50 remains cover the metal gate 42 so as to electrically isolate a metal contact unit 12 (see FIG. 9) formed thereon from the metal gate 42. In the exemplary embodiment shown in FIG. 8, each of the conducting features 32a, 32b, 32c of the conducting unit 32 has a protruding portion protruding away from a top surface of the recessed insulating layer 50. That is, top surfaces of the conducting features 32a, 32b, 32c are at a level higher than the top surface of the insulating layer 50.

Referring to FIG. 1 and the example illustrated in FIG. 9, the method 100 proceeds to step 108, where the metal contact unit 12 is formed in a dielectric portion 62 and over the insulating layer 50, the gate dielectric 40, and the conducting oxide unit 32, in which the metal contact unit 12 is connected to the conducting oxide unit 32.

The metal contact unit 12 (i.e., the drain contact unit for the thin film transistor) is provided to permit charge carriers to exit the channel unit 20 through the metal contact unit 12. In some embodiments, the metal contact unit 12 includes a metal contact 12a formed in a lower dielectric 62a of the dielectric portion 62, a via 12b formed in a middle dielectric 62b of the dielectric portion 62, and a drain contact 12c formed in an upper dielectric 62c of the dielectric portion 62. The metal contact 12a, the via 12b, and the drain contact 12c are connected to each other. Each of the metal contact 12a, the via 12b, and the drain contact 12c is independently made of a material similar to the material of the source contact 11a, the via 11b, and the metal contact 11c as described in FIG. 2. Other suitable materials and/or configurations for the metal contact unit 12 are within the contemplated scope of the present disclosure. The metal contact unit 12 may be formed using any suitable methods known in the art. In some embodiments, the metal contact 12c may have a thickness ranging greater than approximately 5 nm.

As shown in FIG. 9, in accordance with some embodiments, the metal contact unit 12 partially surrounds the conducting oxide unit 32. In other words, the conducting oxide unit 32 vertically protrudes into the metal contact unit 12, and is embedded in the metal contact 12a (of the metal contact unit 12). For instance, the metal contact unit 12 covers a top surface of the conducting oxide unit 32; and partially covers a sidewall of the conducting oxide unit 32. A bottom surface of the conducting oxide unit 32 is located at a level lower than a bottom surface of the metal contact unit 12. More specifically, the top surface of the conducting oxide unit 32 is lower than a top surface of the metal contact 12a and higher than a bottom surface of the metal contact 12a.

After completing step 108, the semiconductor structure 1000, or more specifically the thin film transistor, is obtained. Charge carriers (or a current) are transmitted through the atomic layers of tin monoxide of the vertical channels 20a, 20b, 20c in the vertical direction (or known as the out-of-plane direction) with an excellent hole mobility (as opposed to lateral transmission, i.e., charge carriers are transmitted through the atomic layers of tin monoxide in the horizontal direction, or known as the in-plane direction). In this exemplary embodiment, for each of the vertical channels 20a, 20b, 20c, the lower end and the upper end thereof, that are opposite to each other in the vertical direction, are in direct contact with the conducting oxide units 31, 32 respectively. The metal contact units 11, 12, which are known as the source and drain contact units, are respectively in direct contact with the conducting oxide units 31, 32. As such, the metal contact units 11, 12 are connected to the vertical channels 20a, 20b, 20c of the channel unit 20 through the conducting oxide units 31, 32, respectively, and are opposite to each other in the vertical direction D1. The conducting oxide units 31, 32 allow the channel unit 20 to have better electrical conduction with the source and drain contact units, respectively. In some embodiments, the channel unit 20 has an ohmic contact, or Schottky contact, with the metal contact units 11, 12 (the source and drain contact units) through the conducting oxide units 31, 32, respectively. The conducting oxide unit 32 has portions thereof which protrude away from the top surface of the insulating layer 50 and which are embedded into and surrounded by the metal contact 12a of the metal contact unit 12. FIG. 10 is a horizontal cross sectional view taken along line A-A shown in FIG. 9. As shown in FIG. 10, the channels 20a, 20b, 20c are spaced apart from and are surrounded by the metal gate 42. The channel width (W_{c}), and the thickness (W_{f}) of the vertical channels 20a, 20b, 20c are indicated and as discussed. A portion of the metal gate 42 is omitted to illustrate the first conducting oxide unit 31 underneath the metal gate 42, and a portion of the first conducting oxide unit 31 is omitted to illustrate the metal contact 11c of the first metal contact unit 11 underneath the first conducting oxide unit 31.

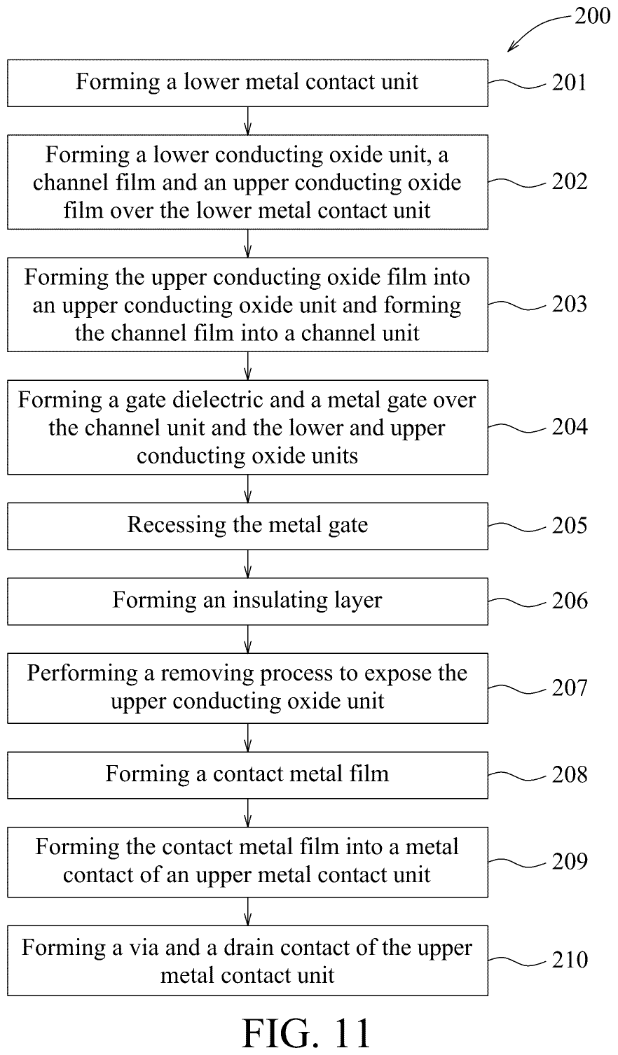

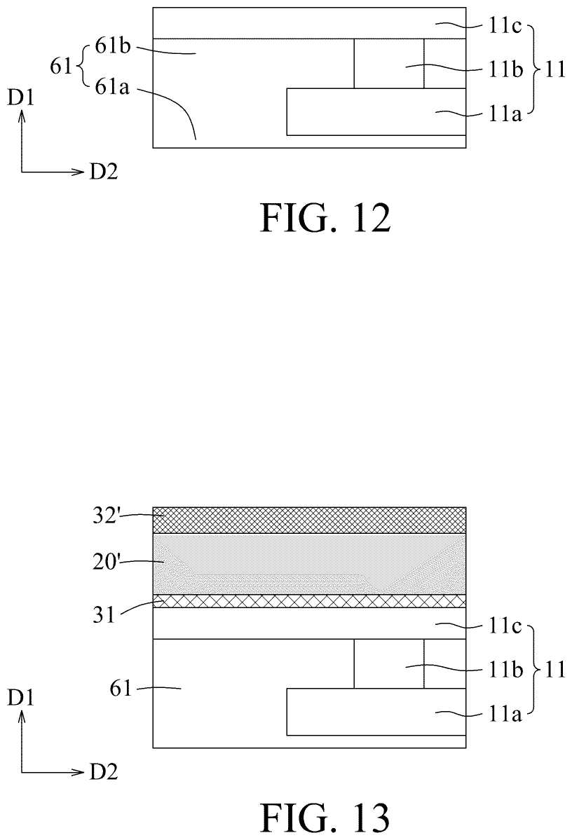

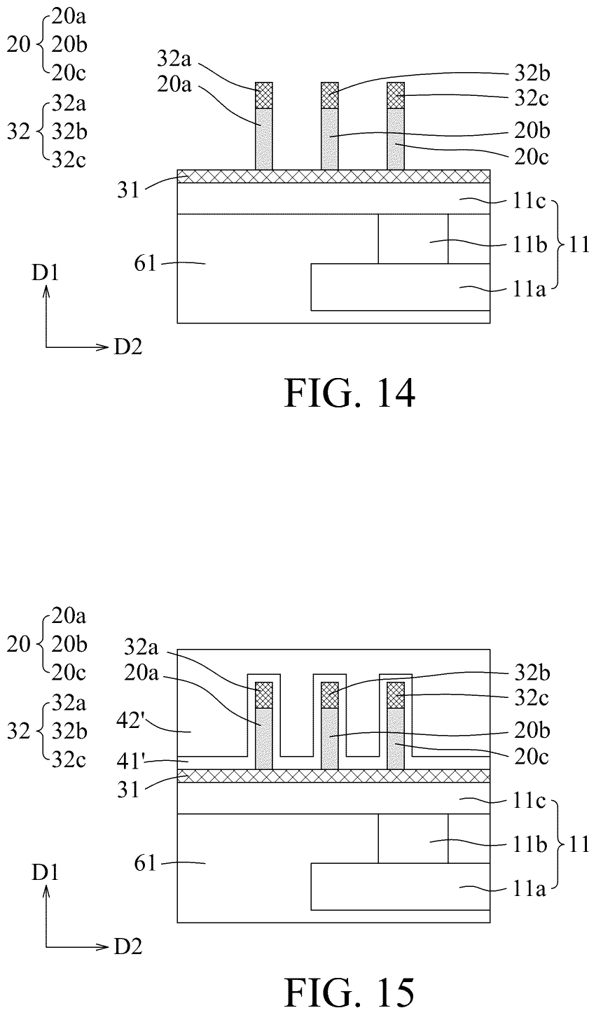

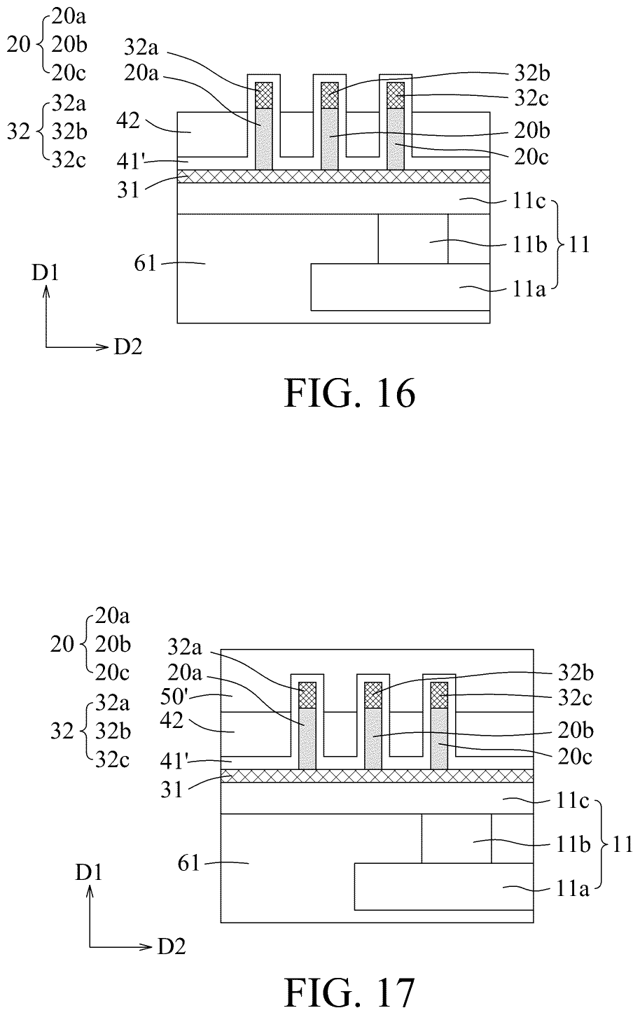

FIG. 11 is a flow diagram illustrating a second method 200 for manufacturing a second semiconductor structure (for example, the semiconductor structure 2000 shown in FIG. 21) in accordance with some embodiments. FIGS. 12 to 21 illustrate schematic views of intermediate stages of the method 200 in accordance with some embodiments. Some repeating structures are omitted in FIGS. 12 to 21 for the sake of brevity. Additional steps can be provided before, after or during the method, and some of the steps described herein may be replaced by other steps or be eliminated.

Referring to FIG. 11 and the examples illustrated in FIGS. 12 to 17, steps 201 to 206 of the method 200 are respectively similar to steps 101 to 106 of the method 100 as described with reference to FIGS. 2 to 7, thus details thereof are omitted for the sake of brevity.

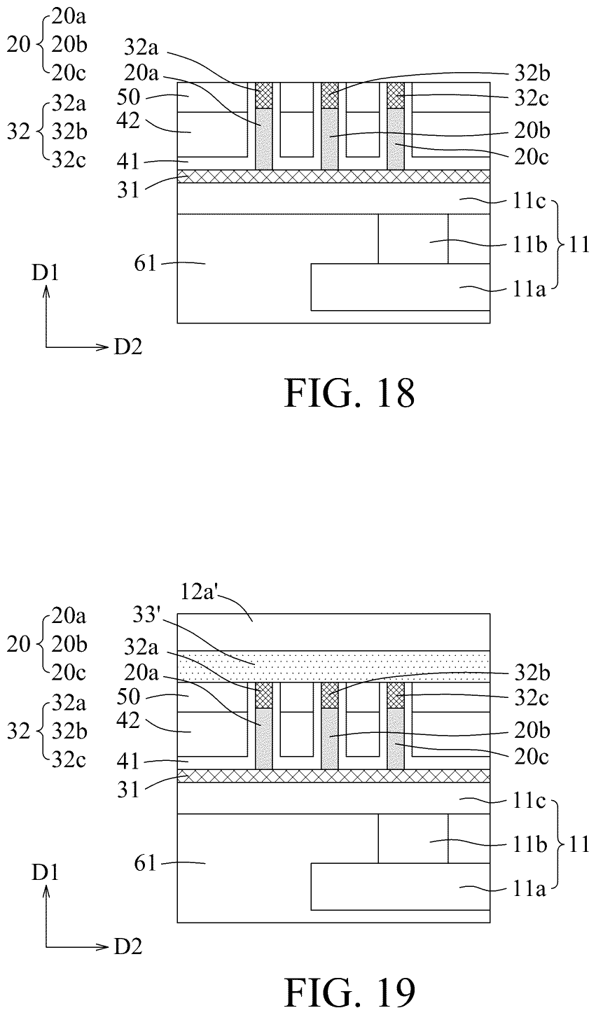

Referring to FIG. 11 and the example illustrated in FIG. 18, the method 200 proceeds to step 207, where a removing process is performed to partially remove the gate dielectric 41′ and the insulating layer 50′, so to expose the conducting oxide unit 32.

The step 207 of the method 200 is similar to the step 107 of the method 100, by including a CMP that removes portions of the insulating layer 50′ and the gate dielectric 41′, so as to expose top surfaces of the conducting features 32a, 32b, 32c underneath. The difference is that, the recessing process as discussed in step 107 is omitted in step 207 of the method 200. After the CMP, the insulating layer is denoted by the numeral 50, and the gate dielectric is denoted by the numeral 41. As such, the structure obtained after step 207 is different from the structure obtained after step 107 (see FIG. 8) in that, as shown in FIG. 18, top surfaces of the conducting features 32a, 32b, 32c of the conducting oxide unit 32 are flush with top surfaces of the insulating layer 50 and the gate dielectric 41.

Referring to FIG. 11 and the example illustrated in FIG. 19, the method 200 proceeds to step 208, where a metal contact film 12a′ is formed over the structure shown in FIG. 18. The metal contact film 12a′ is to be formed into a metal contact 12a of a metal contact unit 12 (see FIG. 21)

In some embodiments, prior to forming the metal contact film 12a′, the method further includes forming a conducting oxide film 33′ over the insulating layer 50 and the conducting oxide unit 32 as shown in FIG. 18. Specifically, the conducting oxide film 33′ is in direct contact with the conducting features 32a, 32b, 32c of the conducting oxide unit 32. In some embodiments, the conducting oxide film 33′ may include a material similar to the materials of the lower conducting oxide film 31 and the upper conducting oxide film 32′ as described with reference to FIG. 3, and details thereof are omitted for the sake of brevity. In some embodiments, the conducting oxide film 33′ may be made of a material identical to the material of the upper conducting oxide film 32′. Other suitable materials for the conducting oxide film 33′ are within the contemplated scope of the present disclosure. The conducting oxide film 33′ may be formed using any suitable methods known in the art. In other embodiments, formation of the conducting oxide film 33′ may be omitted.

The metal contact film 12′ is formed on the conducting oxide film 33′ opposite to the conducting oxide unit 32. The metal contact film 12′ may include a material similar to the material of the metal contact 11c as described with reference to FIG. 2, and details thereof are omitted for the sake of brevity. Other suitable materials for the metal contact film 12a′ are within the contemplated scope of the present disclosure. The metal contact film 12a′ may be formed using any suitable methods known in the art.

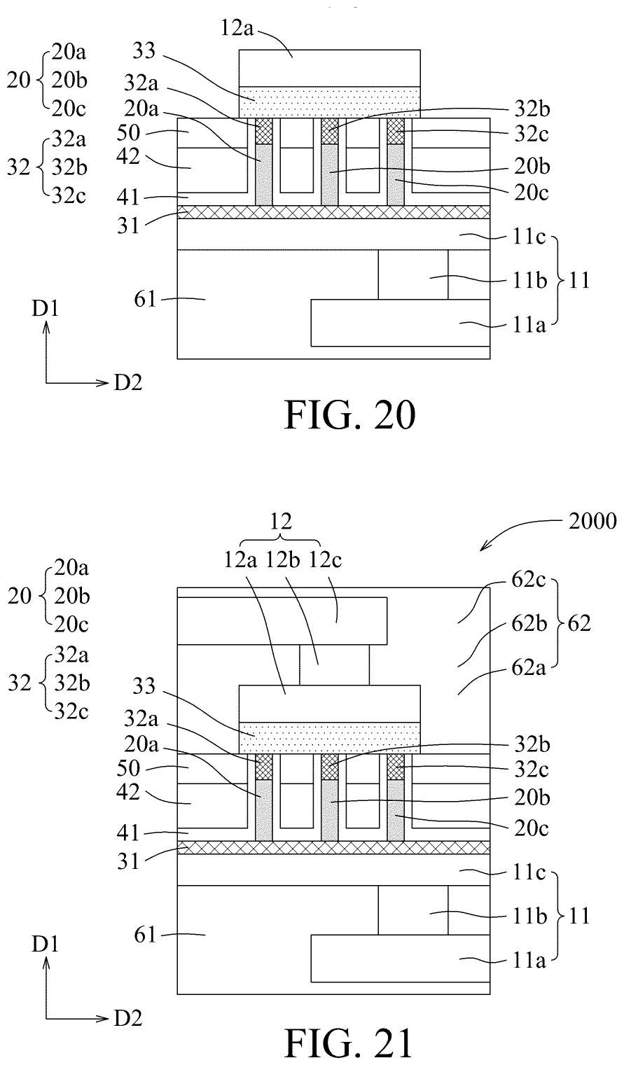

Referring to FIG. 11 and the example illustrated in FIG. 20, the method 200 proceeds to step 209, where a patterning process is performed to form the metal contact film 12a′ into the metal contact 12a that is connected to the conducting oxide unit 32.

Any suitable patterning process known in the art may be used. In some embodiments, the method further includes patterning the conducting oxide film 33′, if any, into a conducting oxide portion 33 through the metal contact 12a. As such, the metal contact 12a is connected to the channel units 20 through the conducting oxide portion 33 and the conducting oxide unit 32. Specifically, the conducting oxide portion 33 is disposed on and in direct contact with each of the conducting features 32a, 32b, 32c of the conducting oxide unit 32. The metal contact 12a is in direct contact with the conducting oxide portion 33.

Referring to FIG. 11 and the example illustrated in FIG. 21, the method 200 proceeds to step 210, where the via 12b and the drain contact 12c of the metal contact unit 12 are formed in the dielectric portion 62.

Specifically, a lower dielectric 62a is formed around the conducting oxide portion 33 and the metal contact 12a. Then a middle dielectric 62b, and an upper dielectric 62c are formed over the lower dielectric 62a. The via 12b is formed in the middle dielectric 62b, and the drain contact 12c is formed in the upper dielectric 62c. The material of each of the dielectric portion 62, the via 12b, and the drain contact 12c may be similar to the material of the dielectric portion 61, the via 11b, the source contact 11a, respectively, and details thereof are omitted for the sake of brevity. The dielectric portion 62, the via 12b, and the drain contact 12c may be formed using any suitable methods known in the art, such a dual damascene process, a single damascene process, or the likes, but are not limited thereto. Other suitable materials and/or methods for forming the metal contact unit 12 and the dielectric portion 62 are within the contemplated scope of the present disclosure.

By completing step 210, the semiconductor structure 2000, or more specifically the thin film transistor, is obtained. The semiconductor structure 2000 is similar to the semiconductor structure 1000, except that the conducting oxide unit 32 is flush with the insulating layer 50 and is not embedded into the metal contact unit 12, but is connected to the metal contact unit 12 through the conducting oxide portion 33. In addition, in the semiconductor structure 2000, both the conducting oxide unit 32 and the conducting oxide portion 33 do not have any protrusions embedded inside the metal contact 12a.

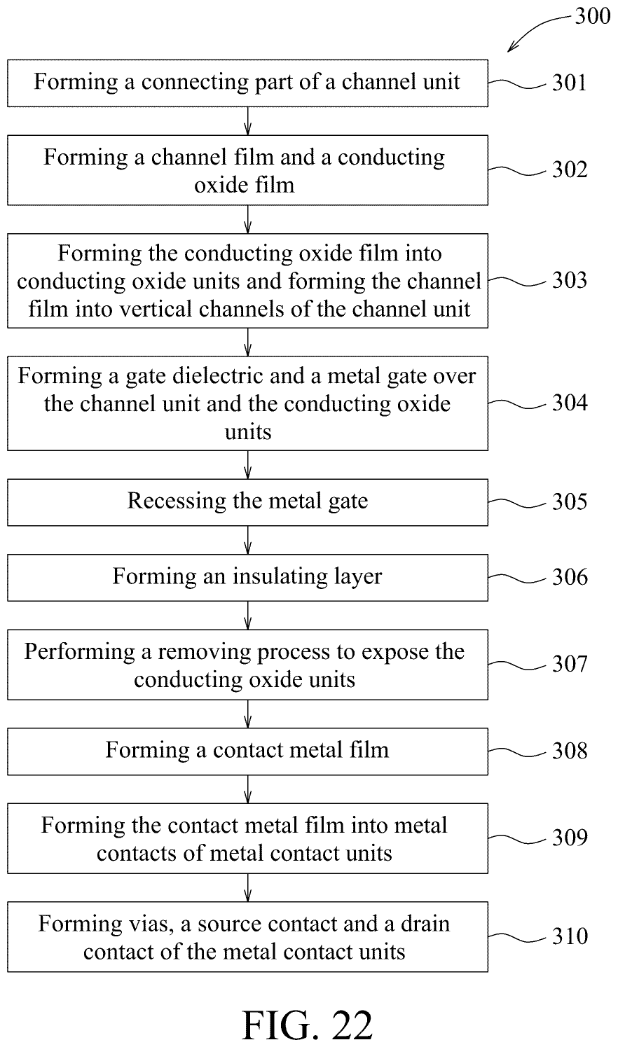

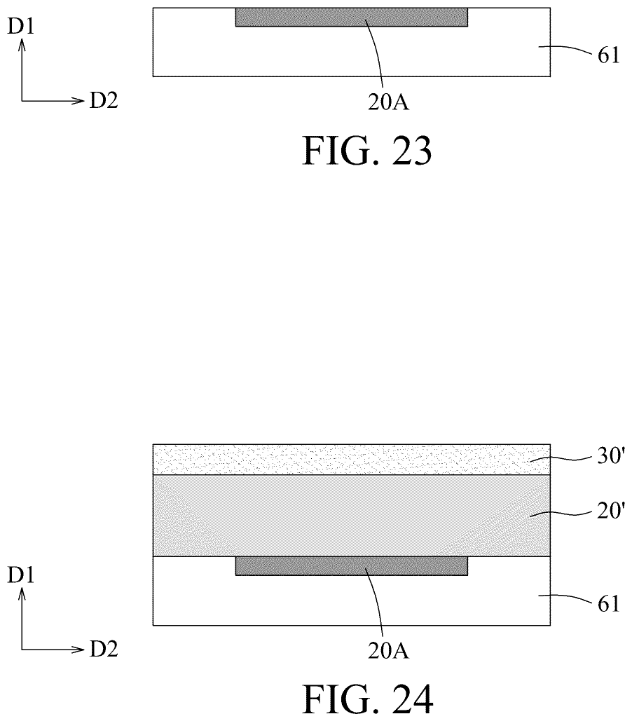

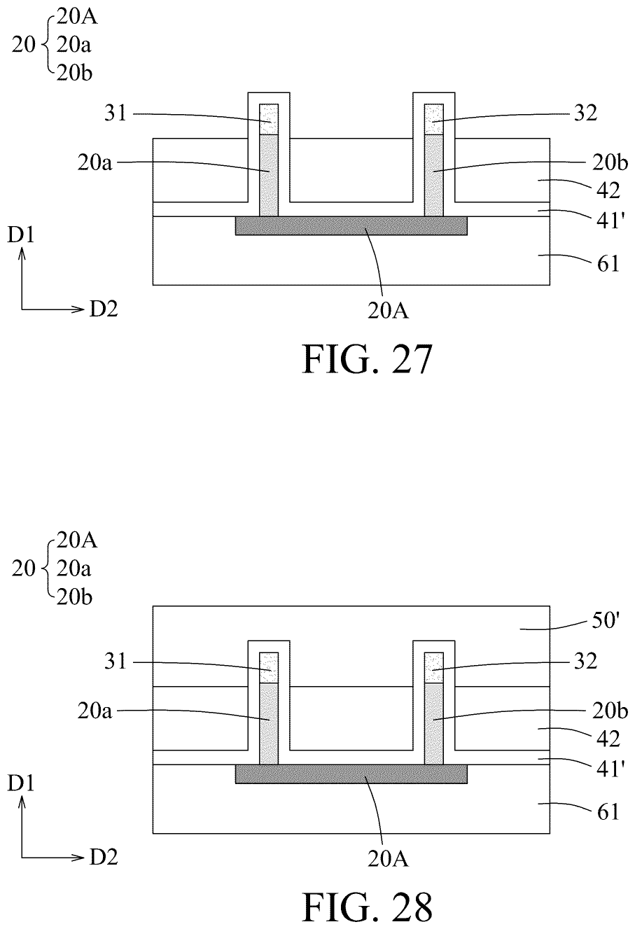

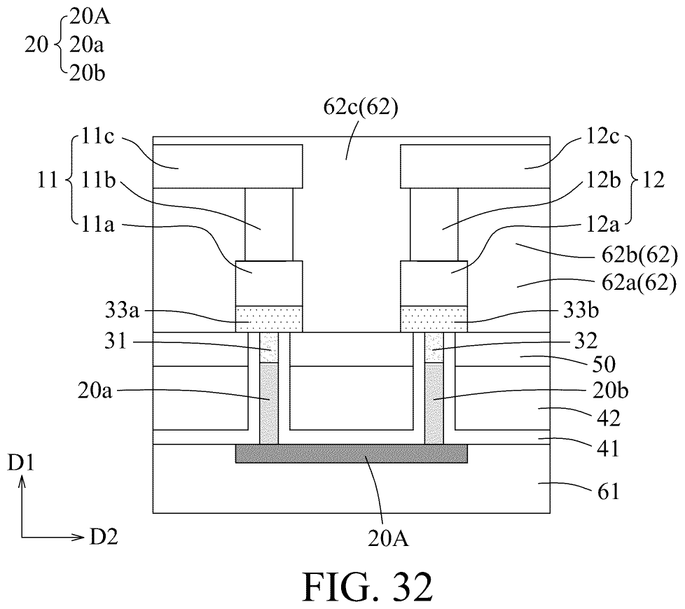

In accordance with some embodiments of the present disclosure, as shown in FIGS. 9 and 21, the metal contact units 11, 12, which are known as the source and drain contact units of the thin film transistor, may be spaced apart from each other in the vertical direction D1 by the channel unit 20. In other embodiments, the metal contact units 11, 12 may also be configured to be spaced apart from each other in the horizontal direction D2. FIG. 22 is a flow diagram illustrating a third method 300 for manufacturing a third semiconductor structure (for example, the semiconductor structure 3000 shown in FIG. 32) in accordance with some embodiments. FIGS. 23 to 32 illustrate schematic views of intermediate stages of the method 300 in accordance with some embodiments. Some repeating structures are omitted in FIGS. 23 to 32 for the sake of brevity. Additional steps can be provided before, after or during the method, and some of the steps described herein may be replaced by other steps or be eliminated.

Referring to FIG. 22 and the example illustrated in FIG. 23, the method 300 begins at step 301, where a connecting part 20A is formed in and exposed from the dielectric portion 61.

The connecting part 20A serves as a part of the channel unit 20 (see FIG. 32), and may have a material similar to, or identical to the material of the channel film 20′ as discussed in step 102 (see FIG. 3), and details thereof are omitted for the sake of brevity. Other details regarding the base structure described in step 301 are similar to those regarding the base structure described in step 101 with reference to FIG. 2, and are omitted for the sake of brevity.

Referring to FIG. 22 and the example illustrated in FIG. 24, the method 300 proceeds to step 302, where the channel film 20′ and a conducting oxide film 30′ are sequentially formed over the dielectric portion 61 and the connecting part 20A.

The channel film 20′ is in direct contact with the connecting part 20A, and the conducting oxide film 30′ is in direct contact with the channel film 20′. The channel film 20′ and the conducting oxide film 30′ in step 302 are respectively similar to the channel film 20′ and the upper conducting oxide film 32′ of step 102 (see FIG. 3), and details thereof are omitted for the sake of brevity. Please note that in step 302, the lower conducting oxide film described in step 102 (see FIG. 3) is omitted.

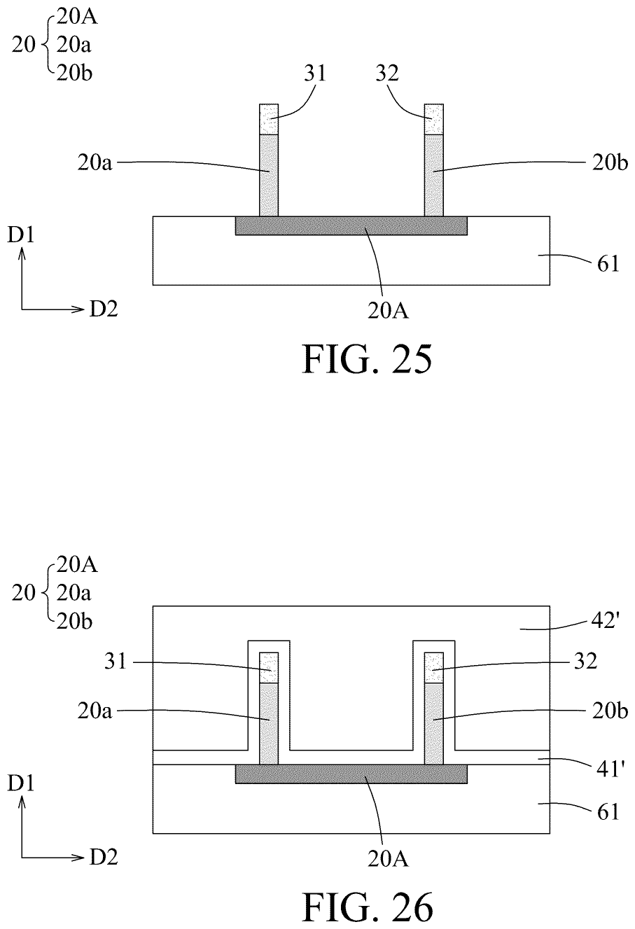

Referring to FIG. 22 and the example illustrated in FIG. 25, the method 300 proceeds to step 303, where a patterning process is performed to form the conducting oxide film 30′ (see FIG. 24) into the conducting oxide units 31, 32; and to form the channel film 20′ (see FIG. 24) into the vertical channels 20a, 20b of the channel unit 20.

In step 303, the channel film 20′ is patterned into at least two vertical channels 20a, 20b, each of which extends in the vertical direction D1 to terminate at the upper end and the lower end. Please note that the number of the vertical channels in step 303 is an even number, as in every two of the vertical channels, one is to be connected to the conducting oxide unit 31, and another one is to be connected to the conducting oxide unit 32. As illustrated in FIG. 25, two of the vertical channels 20a, 20b are formed.

In step 303, each of the vertical channels 20a, 20b is formed to extend from the connecting part 20A in the vertical direction D1 away from the base structure with the lower end thereof in direct contact with the connecting part 20A, such that the two spaced apart vertical channels 20a, 20b are connected to each other through the connect parting 20A. The configuration of the vertical channels 20a, 20b permit charge carriers to be transmitted between the upper end and the lower end of the vertical channels 20a, 20b in the vertical direction D1, and the configuration of the connect part 20A permits charge carriers to be transmitted between the two spaced apart vertical channels 20a, 20b. It is noted that such configuration allows the vertical transmission of charge carriers within parts of the channel unit 20, and at the same time, allows the metal gate 42 (see FIG. 32) to have better control to the channel unit 20 (i.e., improved short channel effect), thereby reduce current leakage.

The conducting oxide units 31, 32 are formed to be spaced apart from and opposite to each other in the horizontal direction D2. In addition, the conducting oxide units 31, 32 are respectively disposed on and in direct contact with the upper ends of the vertical channels 20a, 20b. The conducting oxide unit 31 is to be connected to the metal contact unit 11 (see FIG. 32) which serves as the source contact unit of the thin film transistor; while the conducting oxide unit 32 is to be connected to the metal contact unit 12 which serves as the drain contact unit of the thin film transistor.

The patterning process of step 303 is similar to that of step 103, and details thereof are omitted for the sake of brevity.

Referring to FIG. 22 and the examples illustrated in FIGS. 26 to 28, steps 304 to 306 of the method 300 are respectively similar to steps 104 to 106 of the method 100 as described with reference to FIGS. 5 to 7, thus details thereof are omitted for the sake of brevity.

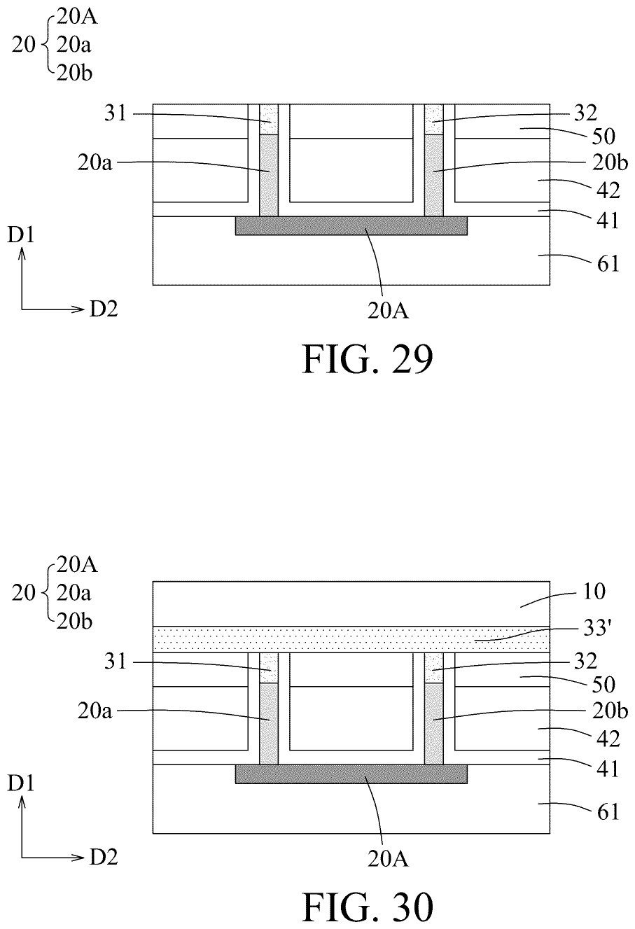

Referring to FIG. 22 and the example illustrated in FIG. 29, the method 300 proceeds to step 307, where a removing process is performed to partially remove the gate dielectric 41′ and the insulating layer 50′ (see FIG. 28), so to expose the conducting oxide units 31, 32.

The removing process may include a CMP process to remove portions of the insulating layer 50′ and the gate dielectric 41′ so as to expose the conducting oxide units 31, 32 underneath. After the CMP, the insulating layer is denoted by the numeral 50, and the gate dielectric is denoted by the numeral 41. In some embodiments, top surfaces of the conducting oxide units 31, 32 are flush with top surfaces of the insulating layer 50 and the gate dielectric 41.

Referring to FIG. 22 and the example illustrated in FIG. 30, the method 300 proceeds to step 308, where a metal contact film 10 is formed over the structure shown in FIG. 29. The metal contact film 10 is to be formed into the metal contact 11a of the metal contact unit 11 (see FIG. 32), and the metal contact 12a of the metal contact unit 12.

In some embodiments, prior to forming the metal contact film 10, the method further includes forming a conducting oxide film 33′ over the structure shown in FIG. 29. That is, the conducting oxide film 33′ is in direct contact with the conducting oxide units 31, 32, and the metal contact film 10. Step 308 is similar to step 208 of the method 200 described with reference to FIG. 19, and thus details thereof are omitted for the sake of brevity.

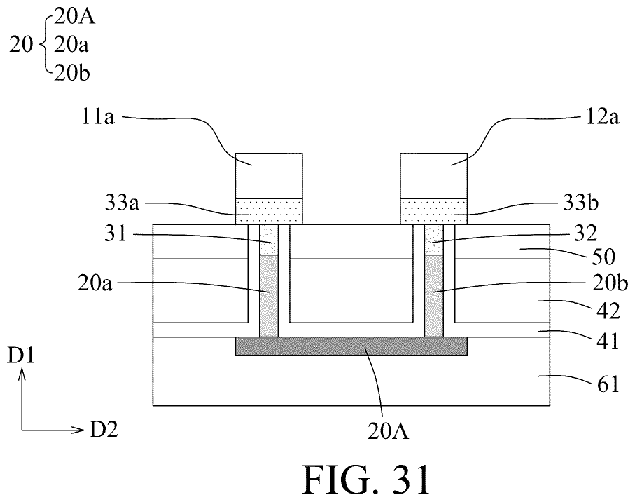

Referring to FIG. 22 and the example illustrated in FIG. 31, the method 300 proceeds to step 309, where a patterning process is performed to form the metal contact film 10 into the metal contact 11a of the metal contact unit 11 and the metal contact 12a of the metal contact unit 12.

Any suitable patterning process known in the art may be used. In some embodiments, the method further includes patterning the conducting oxide film 33′, if any, into a conducting oxide portion 33a through the metal contact 11a, and a conducting oxide portion 33b through the metal contact 12a. As such, the metal contact 11a is connected to the vertical channel 20a through the conducting oxide portion 33a and the conducting oxide unit 31; and the metal contact 12a is connected to the vertical channel 20b through the conducting oxide portion 33b and the conducting oxide unit 32.

Referring to FIG. 22 and the example illustrated in FIG. 32, the method 300 proceeds to step 310, where the via 11b and the source contact 11c of the metal contact unit 11, and the via 12b and the drain contact 12c of the metal contact unit 12 are formed in the dielectric portion 62. After step 310, the conducting oxide portions 33a, 33b and the metal contacts 11a, 12a are located in the lower dielectric 62a.

Step 310 is similar to step 210 of the method 200. In the middle dielectric 62b, the via 11b and the via 12b are formed to be in direct contact with the metal contact 11a and the metal contact 12a, respectively. In the upper dielectric 62c, the source contact 11c and the drain contact 12c are formed to be in direct contact with the via 11b and the via 12b, respectively. Other details thereof are omitted for the sake of brevity.

By completing step 310, the semiconductor structure 3000, or more specifically the thin film transistor, is obtained. The semiconductor structure 3000 is similar to the semiconductor structures 1000, 2000 by all having vertical channels that permit charge carriers to be transmitted therethrough in the vertical direction D1. The difference is, in the semiconductor structure 3000, the metal contact units 11, 12, which respectively serve as the source and drain units of the thin film transistor, are spaced apart from each other in the horizontal direction D2, and both disposed on the upper ends of the vertical channels 20a, 20b. In addition, in the semiconductor structure 3000, the upper end of each of the vertical channels 20a, 20b is in contact with one of the conducting oxide units 31, 32, and the lower end is in contact with the connecting part 20A; in contrast, in the semiconductor structures 1000, 2000, the upper end and lower end of each of the vertical channels 20a, 20b, 20c are respectively in contact with the conducting oxide units 31, 32.

In some embodiments, as described above, in each of the semiconductor structures 1000, 2000, 3000, the metal contact unit 11 serves as the source contact unit and the metal contact unit 12 serves as the drain contact unit; in some other embodiments, in each of the semiconductor structures 1000, 2000, 3000, the metal contact unit 11 serves as the drain contact unit and the metal contact unit 12 serves as the source contact unit.

The embodiments of the present disclosure have the following advantageous features. By virtue of forming the vertical channels with a material that has a high hole mobility in the vertical direction, charge carriers can be transmitted in the vertical direction, and thus are transmitted at a faster speed. In addition, the total channel width of the vertical channels are relatively large, which allows a large current to pass therethrough. Moreover, the gate length of the thin film transistor can be easily and well controlled.

In accordance with some embodiments of the present disclosure, a method for manufacturing a semiconductor structure includes: forming a channel unit on a base structure, the channel unit including at least one vertical channel which extends in a vertical direction to terminate at an upper end and a lower end of the at least one vertical channel; forming a first conducting oxide unit that is disposed on and connected to the upper end of the at least one vertical channel; forming a second conducting oxide unit that is connected to the channel unit and that is spaced apart from the first conducting oxide unit so as to permit charge carriers to be transmitted between the first conducting oxide unit and the second conducting oxide unit through the at least one vertical channel in the vertical direction; forming a gate dielectric over the channel unit, the first conducting oxide unit and the second conducting oxide unit; forming a metal gate over the gate dielectric opposite to the base structure; recessing the metal gate to expose the gate dielectric; and partially removing the gate dielectric to at least expose the first conducting oxide unit.

In accordance with some embodiments of the present disclosure, the method further includes: forming a first metal contact unit over the recessed metal gate such that the first metal contact unit is connected to the first conducting oxide unit, and is electrically isolated from the recessed metal gate; and prior to forming the channel unit, forming a second metal contact unit in the base structure, the second conducting oxide unit being formed over the second metal contact unit before forming the channel unit, such that after forming the channel unit, the lower end of the at least one vertical channel is disposed on and connected to the second conducting oxide unit.

In accordance with some embodiments of the present disclosure, the at least one vertical channel includes vertical channels that are spaced apart from each other in a horizontal direction transverse to the vertical direction; forming the first conducting oxide unit includes forming conducting features which are respectively in direct contact with the upper ends of the vertical channels; and the second conducting oxide unit is in direct contact with the lower ends of the vertical channels.

In accordance with some embodiments of the present disclosure, forming the channel unit, the first conducting oxide unit and the second conducting oxide unit includes: sequentially forming a lower conducting oxide film, a channel film and an upper conducting oxide film over the base structure, the lower conducting oxide film serving as the second conducting oxide unit; and performing a patterning process to form the upper conducting oxide film into the conducting features of the first conducting oxide unit, and to form the channel film into the vertical channels of the channel unit.

In accordance with some embodiments of the present disclosure, the channel unit further includes a connecting part in the base structure, and the at least one vertical channel includes vertical channels extending from the connecting part in the vertical direction opposite to the base structure, the vertical channels being spaced apart from each other in a horizontal direction transverse to the vertical direction and connected to each other through the connecting part; each of the first conducting oxide unit and the second conducting oxide unit being in direct contact with the upper end of a corresponding one of the vertical channels; and after partially removing the gate dielectric, the first conducting oxide unit and the second conducting oxide unit are exposed.

In accordance with some embodiments of the present disclosure, forming the channel unit, the first conducting oxide unit and the second conducting oxide unit includes: forming the connecting part in the base structure; sequentially forming a channel film and a conducting oxide film over the base structure and the connecting part; and performing a patterning process to form the channel film into the vertical channels of the channel unit, and to form the conducting oxide film into the first conducting oxide unit and the second conducting oxide unit.

In accordance with some embodiments of the present disclosure, the method further includes, after recessing the metal gate, forming an insulating layer over the recessed metal gate, and before partially removing the gate dielectric, partially removing the insulating layer so as to expose the gate dielectric.

In accordance with some embodiments of the present disclosure, after partially removing the insulating layer and partially removing the gate dielectric, a top surface of the first conducting oxide unit is flush with a top surface of the partially removed insulating layer.

In accordance with some embodiments of the present disclosure, the method includes forming a conducting oxide portion over the top surfaces of the partially removed insulating layer and the first conducting oxide unit.

In accordance with some embodiments of the present disclosure, after partially removing the insulating layer, the first conducting oxide unit has a protruding portion protruding away from a top surface of the partially removed insulating layer, and the method further includes forming a first metal contact unit that surrounds the protruding portion.

In accordance with some embodiments of the present disclosure, the at least one vertical channel is made of a material such that the charge carriers are transmitted in the vertical direction by a first speed and in a horizontal direction by a second speed, the horizontal direction being transverse to the vertical direction, the first speed being faster than the second speed.

In accordance with some embodiments of the present disclosure, a method for manufacturing a semiconductor structure includes: depositing atomic layers of tin monoxide (SnO) on a base structure along a vertical direction; patterning the atomic layers of tin monoxide into a channel unit; forming a first conducting oxide unit that is connected to the channel unit; forming a second conducting oxide unit that is connected to the channel unit and that is spaced apart from the first conducting oxide unit so as to permit charge carriers to be transmitted between the first conducting oxide unit and the second conducting oxide unit through the patterned atomic layers in the channel unit along the vertical direction; forming a gate dielectric over the channel unit, the first conducting oxide unit and the second conducting oxide unit; forming a metal gate over the gate dielectric opposite to the base structure; recessing the metal gate to expose the gate dielectric; and partially removing the gate dielectric to expose at least the first conducting oxide unit.

In accordance with some embodiments of the present disclosure, the channel unit includes vertical channels that are spaced apart from each other along a horizontal direction transverse to the vertical direction, each of the vertical channels having an upper end and a lower end opposite to each other along the vertical direction.

In accordance with some embodiments of the present disclosure, the first conducting oxide unit includes conducting features, and forming the first conducting oxide unit includes: prior to patterning the atomic layers of tin monoxide, forming an upper conducting oxide film over the atomic layers of tin monoxide; and patterning the upper conducting oxide film into the conducting features, the atomic layers of tin monoxide being patterned into the vertical channels through the conducting features.

In accordance with some embodiments of the present disclosure, the first conducting oxide unit and the second conducting oxide unit are formed by, prior to patterning of the atomic layers of tin monoxide, depositing a conducting oxide film over the atomic layers of tin monoxide, and performing a patterning process to form the conducting oxide film into the first conducting oxide unit and the second conducting oxide unit.

In accordance with some embodiments of the present disclosure, the method further includes, after partially removing the gate dielectric, forming a conducting oxide portion over the exposed first conducting oxide unit.

In accordance with some embodiments of the present disclosure, a semiconductor structure includes a channel unit, a gate dielectric, a metal gate, a first conducting oxide unit, and a second conducting oxide unit. The channel unit is disposed on a base structure, and includes atomic layers that are stacked on each other along a vertical direction. The gate dielectric is disposed on the base structure and surrounding the channel unit. The metal gate is disposed on the gate dielectric. The first conducting oxide unit is in direct contact with the channel unit. The second conducting oxide unit is in direct contact with the channel unit and is spaced apart from the first conducting oxide unit, so as to permit charge carriers to be transmitted between the first conducting oxide unit and the second conducting oxide unit through the atomic layers of the channel unit along the vertical direction.

In accordance with some embodiments of the present disclosure, the semiconductor structure further includes: a first metal contact unit and a second metal contact unit. The first metal contact unit is connected to the first conducting oxide unit so as to permit the first metal contact unit to be in ohmic or Schottky contact with the channel unit through the first conducting oxide unit. The second metal contact unit is connected to the second conducting oxide unit so as to permit the second metal contact unit to be in ohmic or Schottky contact with the channel unit through the second conducting oxide unit.

In accordance with some embodiments of the present disclosure, the channel unit includes vertical channels that are spaced apart from each other along a horizontal direction transverse to the vertical direction. Each of the vertical channels has an upper end and a lower end opposite to each other along the vertical direction.

In accordance with some embodiments of the present disclosure, the first conducting oxide unit and the second connecting oxide unit are located opposite to each other in the vertical direction.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a channel unit on a base structure, the channel unit including at least one vertical channel which extends in a vertical direction to terminate at an upper end and a lower end of the at least one vertical channel;
forming a first conducting oxide unit that is disposed on and connected to the upper end of the at least one vertical channel;
forming a second conducting oxide unit that is connected to the channel unit and that is spaced apart from the first conducting oxide unit so as to permit charge carriers to be transmitted between the first conducting oxide unit and the second conducting oxide unit through the at least one vertical channel in the vertical direction;
forming a gate dielectric over the channel unit, the first conducting oxide unit and the second conducting oxide unit;
forming a metal gate over the gate dielectric opposite to the base structure;
recessing the metal gate to expose the gate dielectric; and
partially removing the gate dielectric to at least expose the first conducting oxide unit.

2. The method as claimed in claim 1, further comprising:
forming a first metal contact unit over the recessed metal gate such that the first metal contact unit is connected to the first conducting oxide unit, and is electrically isolated from the recessed metal gate; and
prior to forming the channel unit, forming a second metal contact unit in the base structure,
the second conducting oxide unit being formed over the second metal contact unit before forming the channel unit, such that after forming the channel unit, the lower end of the at least one vertical channel is disposed on and connected to the second conducting oxide unit.

3. The method as claimed in claim 2, wherein:
the at least one vertical channel includes vertical channels that are spaced apart from each other in a horizontal direction transverse to the vertical direction;
forming the first conducting oxide unit includes forming conducting features which are respectively in direct contact with the upper end of the vertical channels; and
the second conducting oxide unit is in direct contact with the lower ends of the vertical channels.

4. The method as claimed in claim 3, wherein forming the channel unit, the first conducting oxide unit and the second conducting oxide unit includes:
sequentially forming a lower conducting oxide film, a channel film and an upper conducting oxide film over the base structure, the lower conducting oxide film serving as the second conducting oxide unit; and
performing a patterning process to form the upper conducting oxide film into the conducting features of the first conducting oxide unit, and to form the channel film into the vertical channels of the channel unit.

5. The method as claimed in claim 1, wherein:
the channel unit further includes a connecting part in the base structure, and the at least one vertical channel includes vertical channels extending from the connecting part in the vertical direction opposite to the base structure, the vertical channels being spaced apart from each other in a horizontal direction transverse to the vertical direction and connected to each other through the connecting part;
each of the first conducting oxide unit and the second conducting oxide unit being in direct contact with the upper end of a corresponding one of the vertical channels; and
after partially removing the gate dielectric, the first conducting oxide unit and the second conducting oxide unit are exposed.

6. The method as claimed in claim 5, wherein forming the channel unit, the first conducting oxide unit and the second conducting oxide unit includes:
forming the connecting part in the base structure;
sequentially forming a channel film and a conducting oxide film over the base structure and the connecting part; and
performing a patterning process to form the channel film into the vertical channels of the channel unit, and to form the conducting oxide film into the first conducting oxide unit and the second conducting oxide unit.

7. The method as claimed in claim 1, further comprising,
after recessing the metal gate, forming an insulating layer over the recessed metal gate, and
before partially removing the gate dielectric, partially removing the insulating layer so as to expose the gate dielectric.

8. The method as claimed in claim 7, wherein after partially removing the insulating layer and partially removing the gate dielectric, a top surface of the first conducting oxide unit is flush with a top surface of the partially removed insulating layer.

9. The method as claimed in claim 8, further comprising, forming a conducting oxide portion over the top surface of the partially removed insulating layer and the first conducting oxide unit.

10. The method as claimed in claim 7, wherein after partially removing the insulating layer, the first conducting oxide unit has a protruding portion protruding away from a top surface of the partially removed insulating layer, and the method further comprises forming a first metal contact unit that surrounds the protruding portion.

11. The method as claimed in claim 1, wherein the at least one vertical channel is made of a material such that the charge carriers are transmitted in the vertical direction by a first speed and in a horizontal direction by a second speed, the horizontal direction being transverse to the vertical direction, the first speed being faster than the second speed.

12. A method for manufacturing a semiconductor structure, comprising:
depositing atomic layers of tin monoxide (SnO) on a base structure along a vertical direction;
patterning the atomic layers of tin monoxide into a channel unit;
forming a first conducting oxide unit that is connected to the channel unit;
forming a second conducting oxide unit that is connected to the channel unit and that is spaced apart from the first conducting oxide unit so as to permit charge carriers to be transmitted between the first conducting oxide unit and the second conducting oxide unit through the patterned atomic layers in the channel unit along the vertical direction;
forming a gate dielectric over the channel unit, the first conducting oxide unit and the second conducting oxide unit;
forming a metal gate over the gate dielectric opposite to the base structure;
recessing the metal gate to expose the gate dielectric; and
partially removing the gate dielectric to expose at least the first conducting oxide unit.

13. The method as claimed in claim 12, wherein the channel unit includes vertical channels that are spaced apart from each other along a horizontal direction transverse to the vertical direction, each of the vertical channels having an upper end and a lower end opposite to each other along the vertical direction.

14. The method as claimed in claim 13, wherein the first conducting oxide unit includes conducting features, and forming the first conducting oxide unit includes:
prior to patterning the atomic layers of tin monoxide, forming an upper conducting oxide film over the atomic layers of tin monoxide; and
patterning the upper conducting oxide film into the conducting features,
the atomic layers of tin monoxide being patterned into the vertical channels through the conducting features.

15. The method as claimed in claim 13, wherein the first conducting oxide unit and the second conducting oxide unit are formed by, prior to patterning of the atomic layers of tin monoxide, depositing a conducting oxide film over the atomic layers of tin monoxide, and performing a patterning process to form the conducting oxide film into the first conducting oxide unit and the second conducting oxide unit.

16. The method as claimed in claim 12, further comprising, after partially removing the gate dielectric, forming a conducting oxide portion over the exposed first conducting oxide unit.

17. A semiconductor structure, comprising:
a channel unit disposed on a base structure, and including atomic layers that are stacked on each other along a vertical direction;
a gate dielectric disposed on the base structure and surrounding the channel unit;
a metal gate disposed on the gate dielectric;
a first conducting oxide unit that is in direct contact with the channel unit; and
a second conducting oxide unit that is in direct contact with the channel unit and that is spaced apart from the first conducting oxide unit so as to permit charge carriers to be transmitted between the first conducting oxide unit and the second conducting oxide unit through the atomic layers of the channel unit along the vertical direction.

18. The semiconductor structure as claimed in claim 17, further comprising:
a first metal contact unit that is connected to the first conducting oxide unit so as to permit the first metal contact unit to be in ohmic or Schottky contact with the channel unit through the first conducting oxide unit; and
a second metal contact unit that is connected to the second conducting oxide unit so as to permit the second metal contact unit to be in ohmic or Schottky contact with the channel unit through the second conducting oxide unit.

19. The semiconductor structure as claimed in claim 17, wherein the channel unit includes vertical channels that are spaced apart from each other along a horizontal direction transverse to the vertical direction, each of the vertical channels having an upper end and a lower end opposite to each other along the vertical direction.

20. The semiconductor structure as claimed in claim 17, wherein the first conducting oxide unit and the second connecting oxide unit are located opposite to each other in the vertical direction.
